(19) United States
(12) Patent Application Publication
(10) Pub. No.: US 2013/0337171 A1
(43) Pub. Date: Dec. 19, 2013

(54) N2 PURGED O-RING FOR CHAMBER IN CHAMBER ALD SYSTEM

(71) Applicant: QUALCOMM MEMS TECHNOLOGIES, INC., San Diego, CA (US)

(72) Inventor: Teruo Sasagawa, Los Gatos, CA (US)

(73) Assignee: QUALCOMM MEMS TECHNOLOGIES, INC., San Diego, CA (US)

(21) Appl. No.: 13/666,816

(22) Filed: Nov. 1, 2012

Related U.S. Application Data
(60) Provisional application No. 61/659,378, filed on Jun. 13, 2012.

(51) Int. Cl. C23C 16/455; F17D 3/00

(52) U.S. Cl. 427/248.1; 137/1; 118/715

(57) ABSTRACT

This disclosure provides systems, methods and apparatus for purge gas delivery in an atomic layer deposition (ALD) processing apparatus. The ALD processing apparatus can include a processing chamber including a lid and a chamber wall. One or more process gas lines for delivering process gases are coupled to one or more process gas delivery sources in the processing chamber. An o-ring can be positioned proximate an outer edge of the processing chamber to provide a seal with the chamber wall and the lid. The lid is configured to open for removal of the substrate and close to process the substrate. A purge line for delivering purge gas is coupled to one or more purge gas delivery line sources in the processing chamber, and the purge gas delivery line sources are disposed between the o-ring and the one or more process gas delivery sources.

### CROSS-REFERENCE TO RELATED APPLICATION

This application claims priority to U.S. Provisional Patent Application No. 61/659,378 (Attorney Docket No. QUALP154PUS/121438P1), entitled “N2 PURGED O-RING FOR CHAMBER IN CHAMBER ALD SYSTEM,” filed on Jun. 13, 2012, which is hereby incorporated by reference for all purposes.

### TECHNICAL FIELD

This disclosure relates generally to purge gas delivery in atomic layer deposition processing systems.

### DESCRIPTION OF THE RELATED TECHNOLOGY

Deposition of thin films in a reaction chamber can often produce undesirable particle formation in the reaction chamber, including reaction chambers using atomic layer deposition (ALD). The ALD technique includes a sequential introduction of pulses of gases that can result in alternating self-limiting absorption of monolayers of reactants on the surface of a substrate and other exposed surfaces.

ALD systems can confine substantially all deposition gas inside a reaction chamber. Some ALD systems utilize a chamber-in-chamber configuration with the reaction chamber inside an outer chamber. Such a configuration can simplify cleaning as well as improve deposition efficiency in the reaction chamber and minimize cross-contamination with other chambers, for example, in a cluster tool system that includes one or more ALD chambers or sub-chambers as well as chambers for other chemical processes. To clean the reaction chamber, some ALD systems use a replaceable liner structure around the chamber walls. However, undesirable particle formation may still occur outside the liner structure due to gas leaks from the liner structure, which can be very difficult to clean.

### SUMMARY

The systems, methods and devices of the disclosure each have several innovative aspects, no single one of which is solely responsible for the desirable attributes disclosed herein.

One innovative aspect of the subject matter described in this disclosure can be implemented in an atomic layer deposition (ALD) processing apparatus. The ALD processing apparatus can include a processing chamber including a lid; one or more process gas lines coupled to one or more process gas delivery sources in the processing chamber, the one or more process gas delivery sources configured to deliver one or more process gases over a substrate in the processing chamber; an o-ring positioned proximate an outer edge of the processing chamber to seal the processing chamber with the lid, the lid configured to open for removal of the substrate and close to process the substrate; and a purge line coupled to one or more purge gas delivery line sources in the processing chamber, such that the one or more purge gas delivery line sources are disposed between the o-ring and the one or more process gas delivery sources. The purge gas delivery line sources are configured to deliver purge gas into the processing chamber. In some implementations, the apparatus further includes a transfer chamber, with the processing chamber inside the transfer chamber. In some implementations, the one or more purge gas delivery line sources include a groove inside the processing chamber. The groove can be formed in the chamber wall, providing a gas flow of the purge gas into the processing chamber through a gap between the chamber wall and the lid. The dimensions of the gap can be less than the cross-sectional dimensions of the groove. In some implementations, the one or more purge gas delivery line sources include a line of holes. In some implementations, the one or more purge gas delivery line sources are configured to continuously deliver purge gas during delivery of the one or more process gases.

Another innovative aspect of this disclosure can be implemented in an ALD processing apparatus that includes a processing chamber including a lid and a chamber wall; means for delivering one or more process gases over a substrate in the processing chamber; means for sealing the chamber wall and the lid, the sealing means positioned proximate an outer edge of the processing chamber; and means for delivering purge gas into the processing chamber and disposed between the sealing means and the delivering one or more process gases means. The process gas delivery means can be coupled to one or more process gas lines and the purge gas delivery means can be coupled to one or more purge gas delivery line sources. The lid can be configured to open for removal of the substrate and close to process the substrate. In some implementations, the purge gas delivery means continuously delivers purge gas during delivery of the one or more process gases. In some implementations, the purge gas delivery means includes a groove formed in the chamber wall, the groove providing a gas flow of the purge gas into the processing chamber through a gap between the chamber wall and the lid. In some implementations, the one or more purge gas delivery line sources form a purge ring.

Another innovative aspect of this disclosure can be implemented in a method of delivering purge gas in an ALD processing apparatus. The method can include providing a processing chamber including one or more process gas delivery sources, a lid, an o-ring positioned proximate an outer edge of the processing chamber to seal the processing chamber with the lid, and one or more purge gas delivery line sources disposed between the o-ring and the one or more process gas delivery sources; delivering a first reactant gas through the one or more process gas delivery sources into the processing chamber; delivering a second reactant gas through the one or more process gas delivery sources into the processing chamber; and flowing a purge gas through the one or more purge gas delivery line sources during delivery of the reactant gases. In some implementations, flowing the purge gas includes flowing the purge gas from all sides of the processing chamber. In some implementations, flowing the purge gas includes flowing the purge gas continuously during deposition of the reactant gases. In some implementations, the purge gas includes nitrogen. In some implementations, a flow rate of the purge gas is greater than diffusion speeds of each of the reactant gases.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of a schematic cross-sectional side view of an atomic layer deposition (ALD) system with a processing chamber disposed inside a transfer chamber.

FIG. 2 shows an example of a schematic cross-sectional side view of the ALD system in FIG. 1 with the processing chamber opened.

FIG. 3 shows an example of a schematic cross-sectional side view of an ALD system with a chamber lid on a side of a processing chamber.

FIG. 4 shows an example of a schematic top plan view of an ALD system with a purge gas delivery line source according to some implementations.

FIG. 5 shows an example of a schematic top plan view of an ALD system with a purge gas delivery line source according to other implementations.

FIG. 6A shows an example of a purge gas delivery line source with a plurality of holes.

FIG. 6B shows an example of a purge gas delivery line source with a groove.

FIG. 7 shows an example of a flow diagram of a method of delivering purge gas in an ALD processing apparatus.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations pertain to an ALD processing system, which can be implemented in several different tools, including but not limited to single chamber apparatuses, multi-chamber batch processing apparatuses, multi-chamber cluster tools, chamber in chamber apparatuses, etc. Thus, the teachings of the ALD processing system have wide applicability as will be readily apparent to a person having ordinary skill in the art.

In an ALD processing system, a first precursor can be directed over the substrate and some of the first precursor chemisorbs onto a surface of the substrate to form a monolayer. A purge gas can be introduced to remove non-reacted precursors and gaseous reaction by-products. A second precursor can be introduced which can react with the monolayer of the first precursor, with a purge gas subsequently introduced to remove excess precursors and gaseous reaction by-products. This completes one cycle. The precursors are thus alternately pulsed into the reaction chamber without overlap. The cycles can be repeated as many times as desired to form a film of a suitable thickness.

In some implementations, an ALD processing system can substantially confine all deposition gas inside a processing chamber. An o-ring can provide a seal from gas leaks during ALD deposition in the processing chamber. The o-ring can be disposed in a gap between chamber walls and a chamber lid. However, since ALD is a surface-based deposition process, a thin film will form in all exposed surfaces within the processing chamber, including at the o-ring seal. The deposited film may peel off when the film becomes thick, or when the processing chamber is opened, thereby forming particles that can then contaminate the substrates being processed in the chamber. Furthermore, residual particles may form in the processing chamber during deposition, which may form due to trapped precursors such as water in a gap reacting by chemical vapor deposition (CVD). The residual particles formed by CVD may peel off from regions such as the chamber lid or chamber walls in the gap. As a substrate is transferred from the processing chamber to an outer chamber, particles formed by breaking the film from the o-ring surface and the residual particles in the gap can cause device defect, undesirable contamination and non-uniformities in the ALD-deposited thin film.

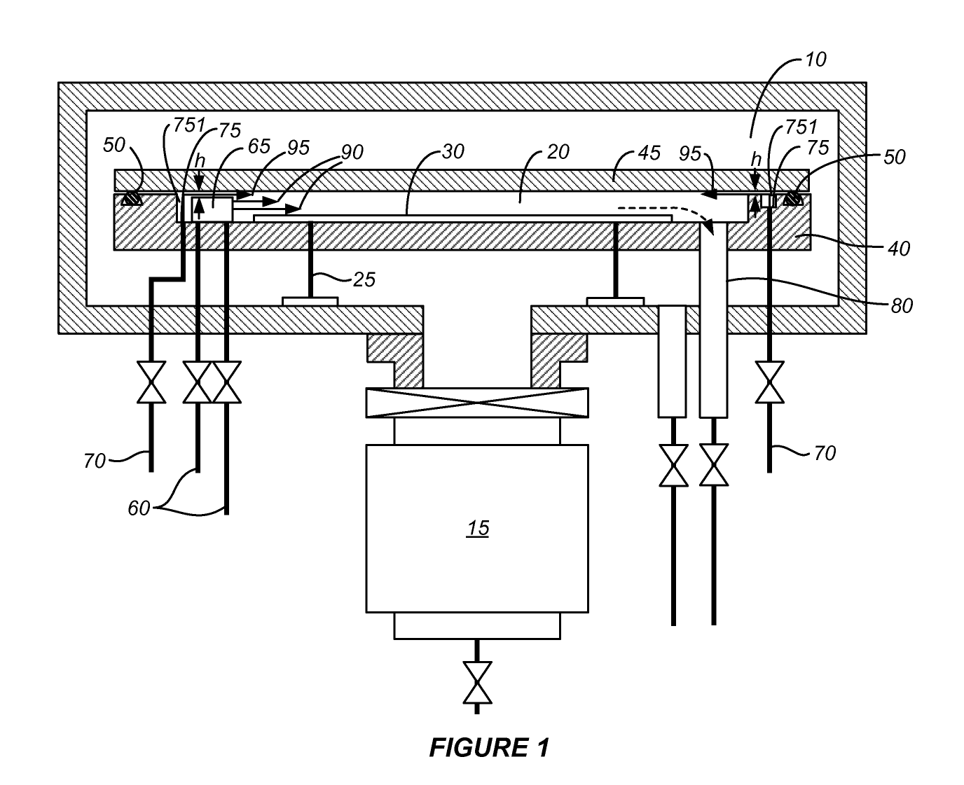

FIG. 1 shows an example of a schematic cross-sectional side view of an ALD system with a processing chamber disposed inside a transfer chamber. The transfer chamber 10 can provide a high vacuum environment. The transfer chamber can include a turbo molecular pump 15 to lower the pressure inside the transfer chamber 10. The transfer chamber 10 can serve as a buffer between a higher pressure processing chamber 20 and an ultra-high vacuum environment in the transfer chamber 10. This arrangement can reduce the effects of cross-contamination and avoid exposing the processing chamber 20 to the outside environment. The processing chamber 20 can be relatively small but have sufficient volume to accommodate a relatively large substrate 30. In some implementations, the processing chamber 20 can have a volume between about 1 liter and about 200 liters (for example, for substrates having one or more sides larger than 3 meters). In some implementations, the processing chamber 20 can have a volume between about 10 to 20 liters, or between about 10 to 15 liters. The ALD system can include a support structure 25 for supporting a substrate 30 inside the processing chamber 20.

The ALD system can also include process gas lines 60 to flow process gases 90 over the substrate 30 in the processing chamber 20. In some implementations, the process gas lines 60 can be coupled to a process gas delivery source 65 positioned inside the processing chamber 20 to deliver the process gases 90. Examples of a process gas delivery source include one or more nozzles. The process gas delivery source 65 can provide sequential introduction of separate pulses of process gases 90 into the processing chamber 20. In some implementations, the pulses are carried by a carrier gas into the processing chamber through the process gas delivery source 65. When the pulses are not injected into the process gas lines 60, the carrier gas can purge the process gas lines 60, the process gas delivery source 65 and the processing chamber 20 from the process gases 90. The process gases 90 can flow over the substrate 30 from one end of the processing chamber 20 to a pump port 80 at another end of the processing chamber 20. In some implementations, the number of process gas lines 60 can depend on the number of reactant gases used. According to various implementations, an ALD system can include one or more process gas lines 60.

An o-ring 50 can be disposed proximate an outer edge of the processing chamber 20. As illustrated in FIG. 1, the o-ring 50 can be in contact with a chamber wall 40 and a chamber lid 45 to provide a seal from the outside environment. The o-ring 50 can provide a vacuum-tight seal and can be made of any suitable elastomeric material. The elastomeric material can have sufficient fatigue resistance such that degradation of elasticity, resiliency, and sealing efficiency over time is minimal. The o-ring 50 can be installed in a shallow slot opening. The o-ring 50 can be any suitable shape, such as a ring or other shape corresponding to the chamber wall 40 and chamber lid 45. The o-ring 50 can create a gap with a height, h, between the chamber wall 40 and the chamber lid 45. The chamber lid 45 can be configured to open for removal or placement of a substrate 30 and close for processing of a substrate 30.

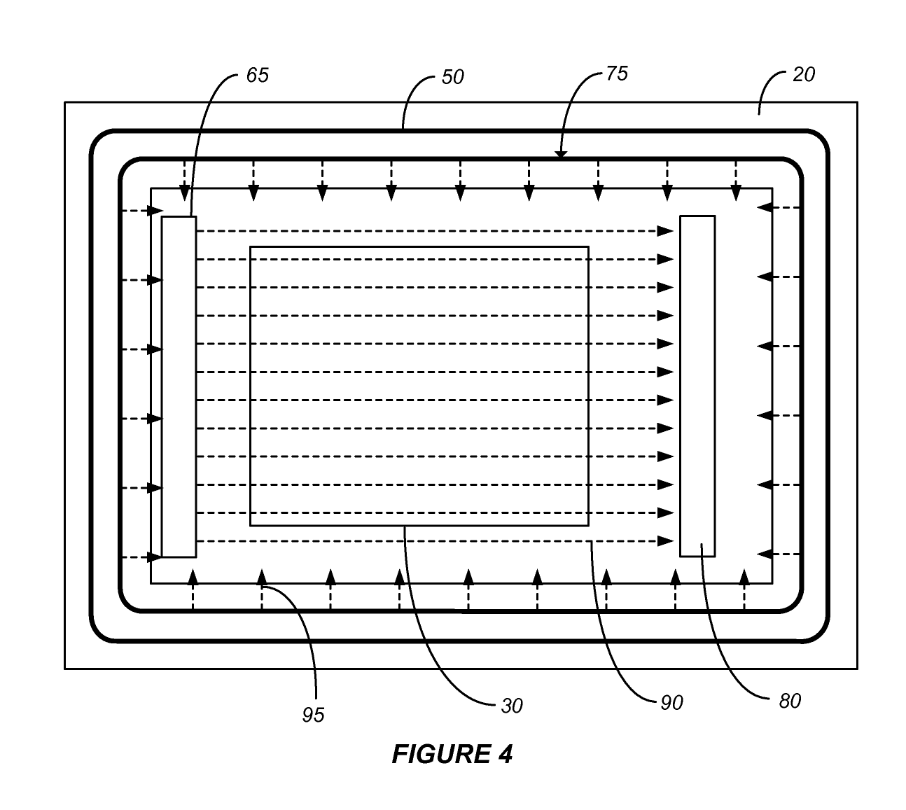

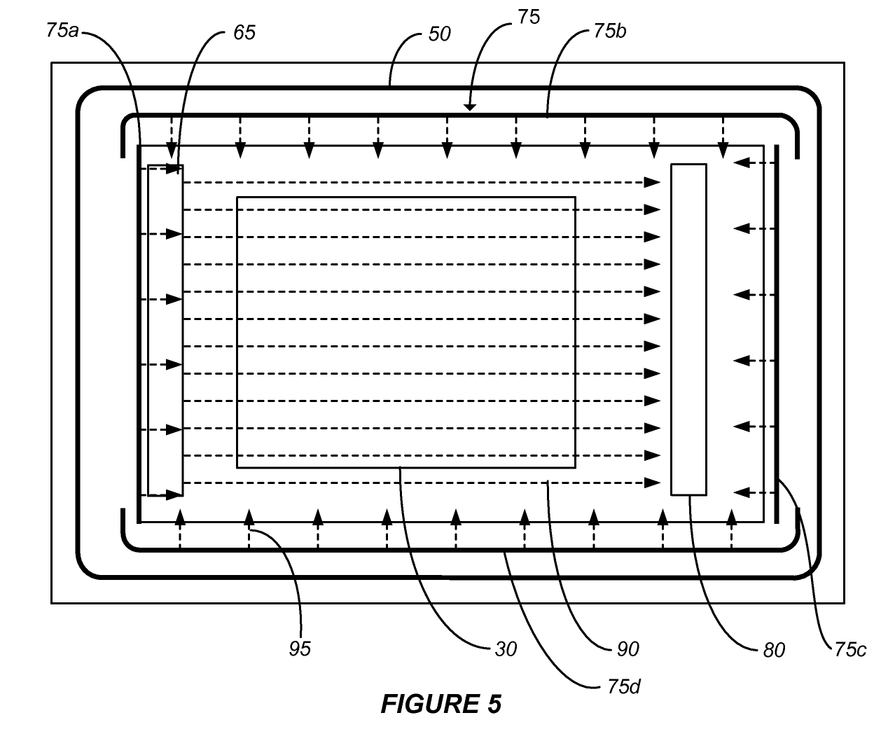

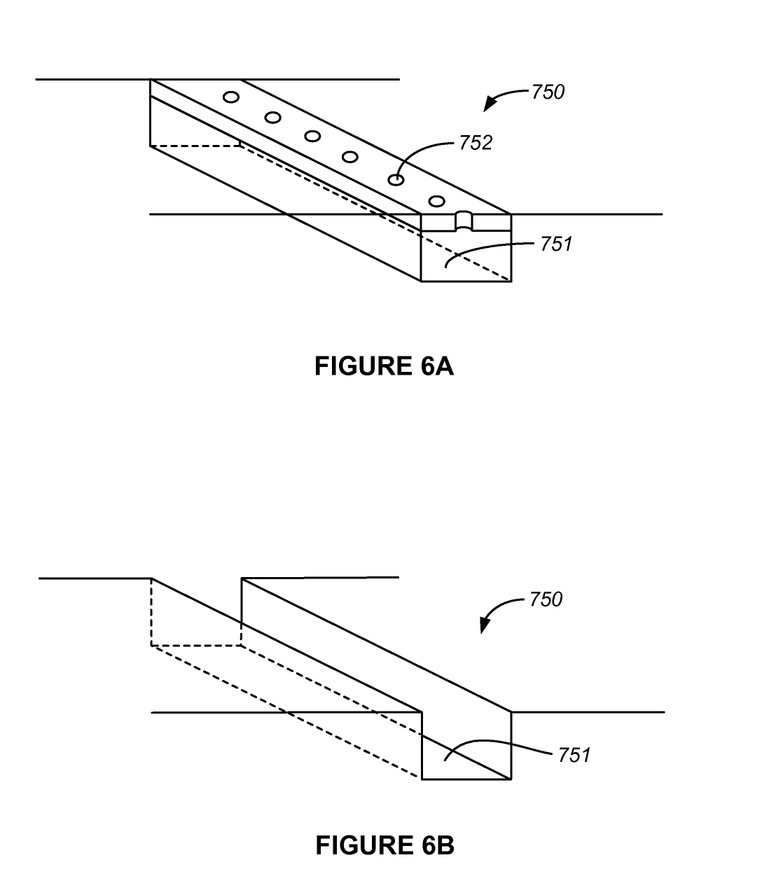

A purge line 70 can be coupled to one or more purge gas delivery line sources 75 in the processing chamber 20. The one or more purge gas delivery line sources 75 can be disposed between process gas delivery source 65 and the o-ring 50. In some implementations, the one or more purge gas delivery line sources 75 can be part of a single line source (such as a continuous purge ring as illustrated in FIG. 4) or multiple line sources (as illustrated in FIG. 5). The one or more purge gas delivery line sources 75 can be configured to flow a purge gas 95 into the processing chamber 20. In some implementations, the one or more purge gas delivery line sources 75 can include a line of holes. Such an implementation is discussed in further detail with respect to FIG. 6A below. In some implementations, the one or more purge gas delivery line sources 75 can include a groove 751 (formed, for example, in the wall 40) from which the purge gas is delivered and flows into the remainder of the processing chamber 20. Such an implementation is discussed in further detail with respect to FIG. 6B below. As illustrated in the example in FIG. 1, the purge gas delivery line source 75 on the right side can include a groove 751 formed between the processing chamber 20 and the o-ring 50, as illustrated in FIG. 1. The purge line 70 may inject purge gas 95 through one or more injection holes into the groove 751.

In some implementations, a gap between the chamber lid and the chamber wall can help provide for uniform flow across the o-ring from the groove 751 into the processing chamber. The gap between the chamber lid 45 and the chamber wall 40 can have a height, h, between about 0.1 mm and about 1 mm, such as about 0.3 mm or 0.5 mm. In one example, the cross sectional area of the groove 751 may be between about 0.5 cm² and about 2 cm², such as about 1 cm². The cross sectional area of the groove 751 can influence the flow rate of the purge gas 95, as the flow rate of the purge gas 95 is dependent on the pressure difference caused by the cross sectional area of the groove 751 and the cross sectional area of the gap. Providing a gap, or other aperture, that separates the groove 751 from the remainder of the processing chamber 20 and that is relatively small, across a cross sectional area of the groove 751 that is relatively large, can help provide a sufficient pressure difference between the purge gas 95 in the groove 751 and the processing chamber 20 to provide for uniform gas flow through the gap or aperture so as to reduce the likelihood of ALD precursor gases reaching the o-ring 50. In some implementations as illustrated, the purge gas delivery line source 75 in areas near the process gas delivery source 65 can be positioned in a space between the chamber lid 45 and the chamber wall 40 and the gap or aperture can be over the space between process gas delivery source 65 and the chamber lid 45 as shown.

In some implementations, the purge gas 95 can include nitrogen (N₂) or other relatively inert gases, such as argon (Ar), helium (He), neon (Ne), and carbon dioxide (CO₂). The purge gas 95 can reduce the amount of process gases 90 from reaching the o-ring 50 and from reaching a gap between the chamber lid 45 and the chamber wall 40 during deposition.

The purge gas delivery line source 75 in the ALD system can provide a flow of purge gas 95 during deposition to prevent undesirable particle buildup in the processing chamber 20. In some implementations, the purge gas 95 is flowed continuously throughout deposition. Depositing a thin film by ALD can include pulsing a first reactant gas followed by pulsing a second reactant gas. By continuously flowing a purge gas 95, the first reactant gas and the second reactant gas is substantially prevented from forming particles by chemical vapor deposition (CVD) within the processing chamber 20 or forming a thin film by ALD throughout the processing chamber 20.

For example, the reactant gases can include precursors such as water (H₂O) and trimethylaluminum (TMA), and the purge gas 95 can substantially prevent the formation of aluminum oxide (Al₂O₃) on chamber components (such as the o-ring 50). It is understood that several other reactant gases can be pulsed for ALD as is known in the art. For example, the reactant gases can form oxide dielectrics such as Al₂O₃, titanium oxide (TiO₂), hafnium oxide (HfO₂), and tantalum oxide (Ta₂O₅), oxide semiconductors/conductors such as indium oxide (In₂O₃), zinc oxide (ZnO), and gallium oxide (Ga₂O₃), and metal nitrides such as titanium nitride (TiN) and tantalum nitride (TaN). Reactant gases can include oxidants such as oxygen (O₂), ozone (O₃), hydrogen peroxide (H₂O₂), alcohols, and the like, and nitrogen-containing compounds such as ammonia (NH₃), hydrazine (N₂H₄), and the like. Reactant gases can include metal halides such as titanium tetrachloride (TiCl₄), hafnium tetrachloride (HfCl₄), and the like, and methylized metals such as trimethyl indium, trimethyl gallium, and dimethyl zinc, and the like.

In some implementations, the purge gas 95 can have a flow rate greater than the diffusion speeds of each of the reactant gases 90. For example, to aid in preventing precursor gas from diffusing toward the o-ring 50, the flow of purge gas 95 through the gap or aperture into the processing chamber 20 can be approximately 10 times the diffusion rate or greater, or approximately 50 times the diffusion rate or greater. It is understood that the diffusion rate can depend upon the precursor material, chamber pressure, temperature, mean free path, and other factors. For example, the purge gas flow rate in standard cubic centimeters per minute (sccm) can be between about 25 sccm and about 1500 sccm, or between about 50 sccm and about 500 sccm. In some implementations, the purge line 70 can include multiple delivery lines coupled to the purge gas delivery line source 75 and each delivery line can be configured to have different flow rates for the different sides of the processing chamber.

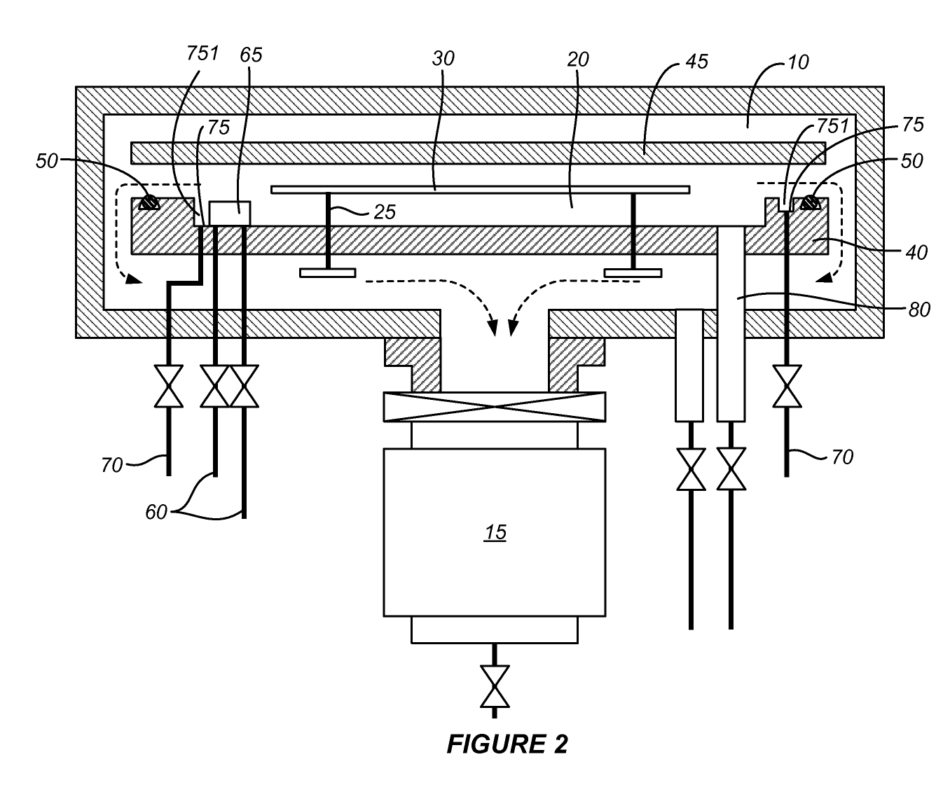

FIG. 2 shows an example of a schematic cross-sectional side view of the ALD system in FIG. 1 with the processing chamber opened. A substrate 30 in the processing chamber 20 can be loaded or unloaded when the chamber lid 45 is opened. While the chamber lid 45 is opened, delivery of the purge gas 95 and process gases 90 can be stopped while the ALD system is pumped down to a high vacuum by the turbo molecular pump 15. Typically, without a purge gas delivery line source 75 between the delivery gas source 65 and the o-ring 50 to deliver purge gas 95 during deposition, particles formed on the o-ring surface and/or residual particles formed in the gap between the chamber lid 45 and the chamber wall 40 can break off when the chamber lid 45 is opened. Such particles can contaminate a thin film (not shown) on the substrate 30 as it is being loaded or unloaded. Contaminate particles can include Al₂O₃, for example, which can form a white powder on the o-ring 50 or on the chamber wall 40 or chamber lid 45. The addition of a purge gas delivery line source 75 between the process gas delivery source 65 and the o-ring 50 substantially prevents the process gases 90 from forming particles by CVD within the processing chamber 20 or forming thin films by ALD throughout the processing chamber 20.

The processing chamber 20 in the example in FIGS. 1 and 2 can be part of a multi-chamber arrangement. For example, as illustrated in FIGS. 1 and 2, the processing chamber 20 can be disposed inside a transfer chamber 10. In some implementations, the processing chamber 20 can be part of a multi-chamber cluster tool. The multi-chamber cluster tool can include a cluster chamber connected to a plurality of chambers that can perform different operations, e.g., deposition, etching, etc., on one or more substrates. In some implementations, the processing chamber 20 can be part of a multi-chamber batch system with a plurality of processing chambers for processing a plurality of substrates.

In some implementations, the substrate 30 can include a glass substrate on which devices such as electromechanical systems (EMS), microelectromechanical systems (MEMS), and/or integrated circuit (IC) devices can be fabricated. For example, the substrate 30 can be a glass substrate panel. A glass substrate panel can have tens to hundreds of thousands or more devices fabricated thereon or attached thereto. In some implementations, ALD processing to deposit layers as part of the fabrication of devices, such as MEMS devices, to form passivation layers, optical layers, mechanical layers, and electrical connections and other signal transmission pathways, occurs at the panel level.

In some implementations, a substrate 30 such as a glass panel can be sized such that the length and width dimensions, also referred to as the lateral dimensions, of the substrate 30 are each greater than 200 mm. In some implementations, the substrate 30 is rectangular. In some implementations, the lateral dimensions of the substrate 30 can be at least 600 mm×800 mm. In some implementations, the lateral dimensions of the substrate 30 can be at least 730 mm×920 mm, at least 1100 mm×1250 mm, or at least 1500 mm×1850 mm. In some implementations, one or both of the width and length can be 1 meter or greater, 2 meters or greater, or 3 meters or greater.

In various implementations, the substrate 30 made of glass is about 100 to 700 microns thick, about 100 to 300 microns thick, about 300 to 500 microns thick, or about 500 microns thick. The substrate 30 may be or include, for example, a borosilicate glass, a soda lime glass, quartz, Pyrex, or other suitable glass material. The substrate 30 may be transparent or non-transparent. For example, the substrate 30 may be frosted, painted, or otherwise made opaque.

The substrate 30 can be a generally planar glass substrate having two substantially parallel surfaces. In some implementations, the EMS, MEMS, or other devices can be built by deposition of various thin film layers and selective patterning of the thin film layers to form the desired devices. In some implementations, some of the thin film layers can be deposited by ALD.

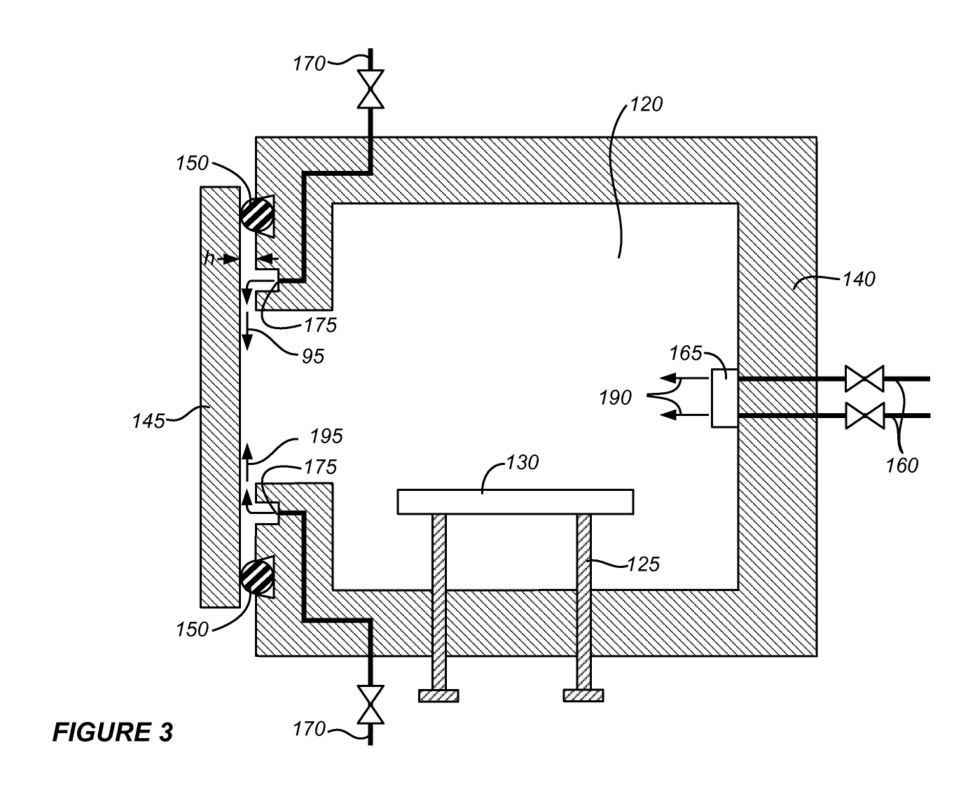

FIG. 3 shows an example of a schematic cross-sectional side view of an ALD system with a chamber lid on a side of a processing chamber. The ALD system can include a support structure 125 for supporting a substrate 130 inside the processing chamber 120. The ALD system can also include process gas lines 160 to flow process gases 190 over the substrate 130 in the processing chamber 120. The process gas lines 160 can be coupled to a process gas delivery source 165 positioned inside the processing chamber 120 to deliver the process gases 190. In some implementations as illustrated in the example in FIG. 3, the process gas delivery source 165 can be positioned on one of the sides of a chamber wall 140 of the processing chamber 120 to flow the process gases 190 over the substrate 130. Alternatively, the process gas delivery source 165 can be positioned on one of the sides of a chamber wall 140 of the processing chamber 120 and oriented above the substrate 130 to shower the process gases 190 onto the substrate 130.

As illustrated in the example in FIG. 3, a chamber lid 145 can be disposed on a side of the processing chamber 120. In some implementations, the side of the processing chamber 120 can include an opening enclosed by the chamber lid 145. The chamber lid 145 can be in contact with an o-ring 150 to provide a seal from the outside environment. The o-ring 150 can be disposed proximate an outer edge of the processing chamber 120 and in contact with the chamber wall 140. In some implementations, the chamber lid 145 can be a door configured to open for removal of a substrate 130 and close for processing of a substrate 130.

A purge line 170 can be coupled to one or more purge gas delivery line sources 175 in the processing chamber 120. The one or more purge gas delivery line sources 175 can be disposed between the process gas delivery source 165 and the o-ring 150. The one or more purge gas delivery line sources 175 can be configured to flow a purge gas 195 into the processing chamber 120. In some implementations, the one or more purge gas delivery line sources 175 can be positioned on the top and the bottom of the chamber wall 140 of the processing chamber 120. The flow of purge gas 195 from the one or more purge gas delivery line sources 175 can substantially reduce the amount of process gases 190 that can flow to the o-ring 150 and to a gap between the chamber lid 145 and the chamber wall 140 during deposition.

FIG. 4 shows an example of a schematic top plan view of an ALD system with a purge gas delivery line source according to some implementations. Process gas lines (not shown) can supply gas to a nozzle or other process gas delivery source 65 to provide a laminar flow of process gases 90 over the substrate 30 from one end of a processing chamber to a pump port 80 at another end of the processing chamber 20. In some implementations, the o-ring 50 can form an annular seal within the processing chamber 20. An o-ring 50 can be positioned around a perimeter of the processing chamber 20. A purge line (not shown) can be coupled to the purge gas delivery line source 75. The purge gas delivery line source 75 can be continuous. At least a portion of the purge gas delivery line source 75 is between the process gas delivery source 65 and the o-ring 50. In some implementations, the purge gas delivery line source 75 can form a purge ring. In some implementations, the purge ring can be radially spaced apart from the o-ring 50. In some implementations, the purge ring delivers purge gas 95 from all sides of the processing chamber 20. In some implementations, the purge gas flowing from the purge ring may form a “gas wall” or a “gas ring” to reduce the amount of ALD precursors delivered via the process gas delivery source 65 that reaches the o-ring 50.

Such a configuration prevents thin film as well as residual particle formation throughout the processing chamber 20, including in places such as the lid (not shown), the o-ring 50, the walls, and the space between the process gas delivery source 65 and the purge gas delivery line source 75. Hence, the purge gas 95 minimizes residual particle formation that could flake off (such as when the lid is opened and closed) and otherwise contaminate or create non-uniformities in an ALD-deposited thin film. Additionally, the purge gas 95 increases the lifetime of the processing chamber 20 by increasing the number of deposition cycles before preventative maintenance is necessary. In some implementations, the number of deposition cycles before preventative maintenance is necessary can be greater than about 1,000 deposition cycles.

FIG. 5 shows an example of a schematic top plan view of an ALD system with a purge gas delivery line source according to some other implementations. The purge gas delivery line source 75 can be discontinuous. Hence, the purge gas delivery line source 75 can include a plurality of line sources 75a, 75b, 75c, and 75d separate from one another. In some implementations, each of the line sources can be coupled to a separate purge line (not shown), and each of the purge lines can be configured to have a different flow rate for different sides of the processing chamber 20. In some implementations, two or more of the line sources can be connected to a common purge line (not shown). As illustrated, in some implementations, the plurality of line sources 75a, 75b, 75c, and 75d overlap around terminal ends of each of the line sources to provide for a robust flow of gas from the periphery of the processing chamber 20 toward the center of the processing chamber 20 to prevent process gases from reaching the o-ring 50. For example, purge gas delivery line sources 75b and 75d can have terminal ends overlap around terminal ends of purge gas delivery line sources 75a and 75c.

FIG. 6A shows an example of a purge gas delivery line source with a plurality of holes. The plurality of holes 752 may be a line of holes along the length of the purge gas delivery line source 750. Purge gas may flow through a groove 751 in the purge gas delivery line source 750 and flow through each of the holes 752 into a processing chamber. In some implementations, the plurality of holes 752 may be parallel with the purge gas delivery line source 750. In some implementations, the plurality of holes 752 may be uniformly spaced apart. As discussed above in relation to the groove 751 of FIG. 1, gas flow from the groove 751 of the purge gas delivery line source 750 into the processing chamber may be restricted by one or more apertures so as to allow for a uniform pressure of the purge gas inside the groove 751 that is higher than the pressure inside the processing chamber to allow for uniform gas flow across the line source. In the illustrated implementation of FIG. 6A, the aperture(s) include one or more holes.

FIG. 6B shows an example of a purge gas delivery line source with a groove. Purge gas may flow through the groove 751 in the purge gas delivery line source 750 and spread out from the purge gas delivery line source 750 into a processing chamber. In some implementations, the groove 751 can be between about 8 mm and about 15 mm deep, and be between about 5 mm and about 15 mm wide. As discussed above in relation to the groove 751 of FIG. 1, gas flow from the groove 751 of the purge gas delivery line source into the processing chamber may be restricted by a gap or aperture so as to allow for a uniform pressure of the purge gas inside the groove 751 that is higher than the pressure inside the processing chamber to allow for uniform gas flow across the line source. In the implementations illustrated in FIGS. 1 and 2, the gap or aperture can include a small gap with a height h between the chamber wall and the chamber lid. In such implementations, the groove 751 may be formed in the chamber wall.

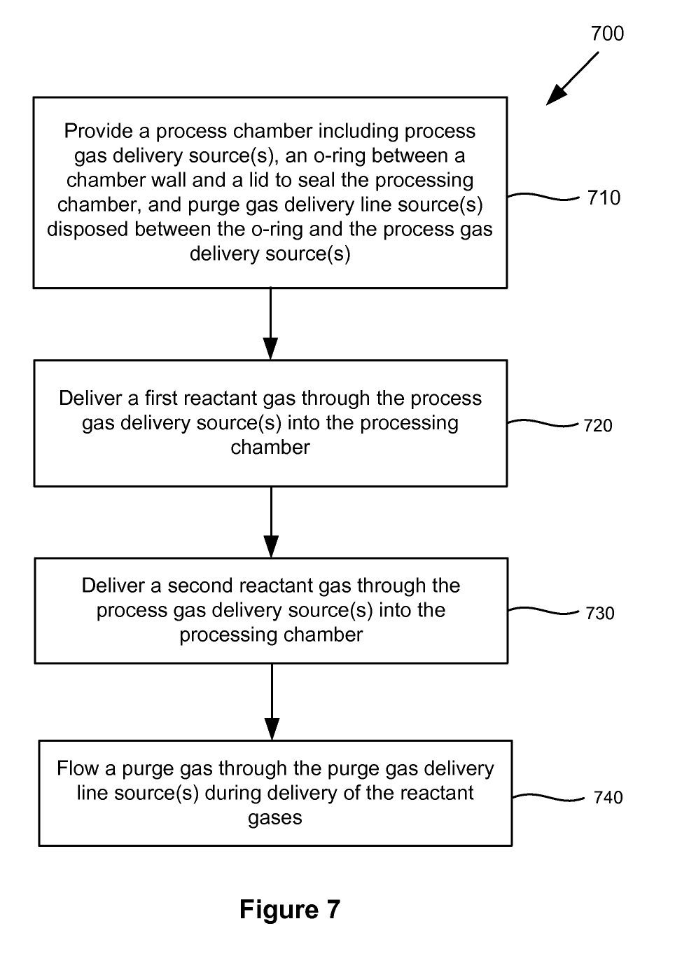

FIG. 7 is a flow diagram of a method of delivering purge gas in an ALD processing apparatus. It is understood that additional processes not shown in FIG. 7 may also be present.

The process 700 begins at block 710 where a processing chamber is provided. The processing chamber includes one or more process gas delivery sources, a lid, a chamber wall, an o-ring positioned proximate an outer edge of the processing chamber and between the chamber wall and the lid to seal the processing chamber with the lid, and one or more purge gas delivery line sources disposed between the o-ring and the one or more process gas delivery sources. In some implementations, the one or more purge gas delivery line sources include a groove inside the processing chamber. In some implementations, the one or more purge gas delivery line sources include a line of holes.

The process 700 continues at block 720 where a first reactant gas is delivered through the one or more process gas delivery sources into the processing chamber. In some implementations, the first reactant gas can include any ALD precursor known in the art or discussed earlier herein, such as TMA. The first reactant gas can flow over a substrate from one end of the processing chamber to a pump port at another end of the processing chamber. The first reactant gas can chemisorb onto a surface of the substrate to form a monolayer.

The process 700 continues at block 730 where a second reactant gas is delivered through the one or more process gas delivery sources into the processing chamber. In some implementations, the second reactant gas can include any ALD precursor known in the art or discussed earlier herein, such as water. The second reactant gas can flow over a substrate from one end of the processing chamber to a pump port at another end of the processing chamber. The second reactant gas can react with the monolayer on the surface of the substrate.

The process 700 continues at block 740 where a purge gas is flowed through the one or more purge gas delivery line sources during delivery of the reactant gases. In some implementations, the purge gas includes nitrogen. In some implementations, flowing the purge gas includes flowing the purge gas from all sides of the processing chamber. In some implementations, flowing the purge gas includes forming a gas curtain to reduce the amount of reactant gases from reaching the o-ring. In some implementations, flowing the purge gas includes flowing the purge gas continuously during deposition of the reactant gases. In some implementations, a flow rate of the purge gas is greater than diffusion speeds of each of the reactant gases.

Various modifications to the implementations described in this disclosure may be readily apparent to those having ordinary skill in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An atomic layer deposition (ALD) processing apparatus, comprising:
a processing chamber including a lid and a chamber wall;
one or more process gas lines coupled to one or more process gas delivery sources in the processing chamber, the one or more process gas delivery sources configured to deliver one or more process gases over a substrate in the processing chamber;
an o-ring positioned proximate an outer edge of the processing chamber to provide a seal with the chamber wall and the lid, the lid configured to open for removal of the substrate and close to process the substrate; and
a purge line coupled to one or more purge gas delivery line sources in the processing chamber, wherein the one or more purge gas delivery line sources are disposed between the o-ring and the one or more process gas delivery sources, wherein the purge gas delivery line sources are configured to deliver purge gas into the processing chamber.

2. The apparatus of claim 1, further comprising a transfer chamber, wherein the processing chamber is inside the transfer chamber.

3. The apparatus of claim 1, wherein the one or more purge gas delivery line sources include a groove inside the processing chamber.

4. The apparatus of claim 3, wherein the groove is formed in the chamber wall, the groove providing a gas flow of the purge gas into the processing chamber through a gap between the chamber wall and the lid.

5. The apparatus of claim 4, wherein dimensions of the gap are less than cross-sectional dimensions of the groove.

6. The apparatus of claim 5, wherein the gap has a height between about 0.1 mm and about 1.0 mm, and the cross-sectional area of the groove is between about 0.5 cm² and about 2.0 cm².

7. The apparatus of claim 1, wherein the one or more purge gas delivery line sources include a line of holes.

8. The apparatus of claim 1, wherein the one or more purge gas delivery line source are configured to continuously deliver purge gas during delivery of the one or more process gases.

9. The apparatus of claim 1, wherein the purge gas includes nitrogen.

10. The apparatus of claim 1, wherein the one or more purge gas delivery line sources are configured to deliver purge gas from all sides of the processing chamber.

11. The apparatus of claim 1, wherein the one or more purge gas delivery line sources are continuous.

12. The apparatus of claim 1, wherein the one or more purge gas delivery line sources form a purge ring.

13. The apparatus of claim 1, wherein the one or more purge gas delivery line sources are discontinuous.

14. The apparatus of claim 13, wherein the one or more purge gas delivery line sources form a plurality of purge gas delivery line sources.

15. The apparatus of claim 1, wherein the processing chamber is part of a multi-chamber cluster tool.

16. An atomic layer deposition (ALD) processing apparatus, comprising:
a processing chamber including a lid and a chamber wall;
means for delivering one or more process gases over a substrate in the processing chamber, the process gas delivery means coupled to one or more process gas lines;
means for sealing the chamber wall and the lid, the sealing means positioned proximate an outer edge of the processing chamber, the lid configured to open for removal of the substrate and close to process the substrate; and
means for delivering purge gas into the processing chamber, the purge gas delivery means disposed between the sealing means and the process gas delivery means, the purge gas delivery means coupled to one or more purge gas delivery line sources.

17. The apparatus of claim 16, wherein the purge gas delivery means continuously delivers purge gas during delivery of the one or more process gases.

18. The apparatus of claim 16, wherein the sealing means includes an o-ring.

19. The apparatus of claim 16, wherein the purge gas delivery means includes a groove formed in the chamber wall, the groove providing a gas flow of the purge gas into the processing chamber through a gap between the chamber wall and the lid.

20. A method of delivering purge gas in an atomic layer deposition (ALD) processing apparatus, comprising:
providing a processing chamber including one or more process gas delivery sources, a lid, a chamber wall, an o-ring positioned between the chamber wall and the lid to seal the chamber wall with the lid, and one or more purge gas delivery line sources disposed between the o-ring and the one or more process gas delivery sources;
delivering a first reactant gas through the one or more process gas delivery sources into the processing chamber;
delivering a second reactant gas through the one or more process gas delivery sources into the processing chamber; and
flowing a purge gas through the one or more purge gas delivery line sources during delivery of the reactant gases.

21. The method of claim 20, wherein flowing the purge gas includes flowing the purge gas from all sides of the processing chamber.

22. The method of claim 20, wherein flowing the purge gas includes forming a gas curtain to reduce the amount of reactant gases from reaching the o-ring.

23. The method of claim 20, wherein flowing the purge gas includes flowing the purge gas continuously during deposition of the reactant gases.

24. The method of claim 20, wherein the purge gas includes nitrogen.

25. The method of claim 20, wherein the one or more purge gas delivery line sources include a groove inside the processing chamber.

26. The method of claim 20, wherein the one or more purge gas delivery line sources include a line of holes.

27. The method of claim 20, wherein a flow rate of the purge gas is greater than diffusion speeds of each of the reactant gases.

28. The method of claim 27, wherein the flow rate of the purge gas is at least 10 times greater than the diffusion speeds of any of the reactant gases.
